(19) United States
(12) Patent Application Publication
(10) Pub. No.: US 2024/0284730 A1
(43) Pub. Date: Aug. 22, 2024

(54) FLEXIBLE ELECTROLUMINESCENT DISPLAY DEVICE

(71) Applicant: LG DISPLAY CO., LTD., Seoul (KR)

(72) Inventors: Neunghee LEE, Seoul (KR); Seunghyun KIM, Goyang-si (KR)

(73) Assignee: LG DISPLAY CO., LTD., Seoul (KR)

(21) Appl. No.: 18/417,572

(22) Filed: Jan. 19, 2024

(30) Foreign Application Priority Data
Feb. 16, 2023 (KR) 10-2023-0020434

(51) Int. Cl. H10K 59/131; H10K 102/00

(52) U.S. Cl. CPC H10K 59/131; H10K 2102/311

(57) ABSTRACT

A display device includes a flexible substrate including an active area including a plurality of pixels and a non-active area adjacent to the active area, the non-active area including a bending area bendable in a first direction; a pattern unit disposed on the flexible substrate in the bending area and including concave portions and convex portions; and a plurality of lines disposed on the pattern unit.

### CROSS-REFERENCE TO RELATED APPLICATION

This application claims the priority of Korean Patent Application No. 10-2023-0020434 filed on Feb. 16, 2023, which is hereby incorporated by reference in its entirety.

### BACKGROUND

### Field of the Disclosure

The present disclosure relates to a flexible electroluminescent display device and a manufacturing method thereof, and more specifically, to a flexible electroluminescent display device allowing for an improvement of a bending area of the flexible electroluminescent display device and a manufacturing method thereof.

### Description of the Background

As our society advances toward information-oriented society, the field of display devices for visually expressing an electrical information signal has rapidly advanced. Various display devices having excellent performance in terms of thinness, lightness, and low power consumption, are being developed correspondingly.

Representative display devices may include a liquid crystal display (LCD) device, a field emission display (FED) device, an electro-wetting display (EWD) device, an organic light emitting display (OLED) device, and the like.

Electroluminescent display devices, including organic light emitting display devices, are self-emissive display devices, and may be manufactured to be light and thin since they do not require a separate light source, unlike liquid crystal displays having a separate light source. In addition, the electroluminescent display devices have advantages in terms of power consumption due to a low voltage driving, and are excellent in terms of a color implementation, a response speed, a viewing angle, and a contrast ratio (CR). Therefore, the electroluminescent display devices have been expected to be used in various application fields.

In the electroluminescent display device, an emissive layer (EML) formed of an organic material is disposed between two electrodes, an anode and a cathode. When holes from the anode are injected into the emission layer and electrons from the cathode are injected into the emission layer, the injected electrons and holes recombine with each other to form excitons in the emission layer and emit light.

In addition, the emission layer contains a host material and a dopant material, and interaction between the two materials occurs therein. The host serves to generate excitons from the electrons and holes and transfer energy to a dopant. The dopant is a dye-like organic substance added in a small amount and serves to receive energy from a host and convert it into light.

An electroluminescent display device including an emission layer formed of an organic material encapsulates the electroluminescent display device with glass, metal, or film to prevent an introduction of moisture or oxygen into the electroluminescent display device from the outside. Thus, the electroluminescent display device prevents oxidation of the emission layer and electrodes, and protects them from external mechanical or physical impacts.

### SUMMARY

As display devices become smaller, efforts to reduce a bezel area outside an active area are being made to increase a size of an effective display screen in the same area of the display device.

Since lines and driving circuits for driving the screen are generally disposed in the bezel area, which is a non-active area, there are a limit to reducing the bezel area.

In recently developed flexible electroluminescent display devices that may maintain display performance even when bent by applying a flexible substrate formed of a ductile material such as plastic, a non-active area of a flexible substrate may be bent to reduce a bezel area while securing an area for lines and driving circuits.

When forming lines in a bending area B/A, stress due to bending may be applied to the lines. To reduce stress and prevent damage due to bending, lines with a curved (or uneven) structure may be formed. A pattern unit may be formed to form a curved (or uneven) line structure, and the pattern unit may have concave portions and convex portions.

Accordingly, the present disclosure is directed to a flexible electroluminescent display device that substantially obviates one or more of problems due to limitations and disadvantages described above.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device according to an exemplary aspect of the present disclosure includes a flexible substrate including an active area including a plurality of pixels and a non-active area adjacent to the active area, the non-active area including a bending area bent in a first direction; a pattern unit disposed on the flexible substrate in the bending area and including concave portions and convex portions; and a plurality of lines disposed on the pattern unit.

In another aspect of the present disclosure, a flexible display device includes a substrate including an active area having a plurality of pixels and a non-active area having a bending area bendable along a bending direction; a plurality of stress reducing parts disposed on the flexible substrate in the bending area and extending along the bending direction or a different direction from the bending direction; a plurality of circuit lines disposed to match a contour of the plurality of stress reducing parts and extending along the different direction from the bending direction; and a circuit line protecting layer covering the plurality of circuit lines.

The display device according to an exemplary aspect of the present disclosure has effects of reducing damage due to stress caused by bending of bent lines formed on concave portions and convex portions in a bending area by forming patterns on an insulating layer formed under the lines.

The display device according to an exemplary aspect of the present disclosure has effects of reducing stress of lines in a bending area due to variations in a neutral plane that may occur due to process deviation.

The present disclosure is not limited to the contents exemplified above, and more various effects are included in the present disclosure.

It is to be understood that both the foregoing general description and the following detailed description of the present disclosure are exemplary and explanatory and are not intended to specify essential limitations recited in the claims. Therefore, the scope of the claims is not restricted by the foregoing general description and the following detailed description of the present disclosure.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a plan view of a display device according to an exemplary aspect of the present disclosure;

FIG. 2 is a cross-sectional view of the display device according to an exemplary aspect of the present disclosure;

FIGS. 3A and 3B are detailed structures of a bending area according to an exemplary aspect of the present disclosure;

FIGS. 4A and 4B are detailed structures of a bending area according to an exemplary aspect of the present disclosure;

FIGS. 5A and 5B are detailed structures of a bending area according to an exemplary aspect of the present disclosure;

FIGS. 6A and 6B are detailed structures of a bending area according to an exemplary aspect of the present disclosure;

FIG. 7 is a plan view of a detailed structure of a bending area according to an exemplary aspect of the present disclosure;

FIG. 8 is a cross-sectional view of a detailed structure of a bending area according to an exemplary aspect of the present disclosure; and

FIG. 9 is a cross-sectional view of a bending area of a display device according to an exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, a display device according to exemplary aspects of the present disclosure will be described in detail with reference to accompanying drawings.

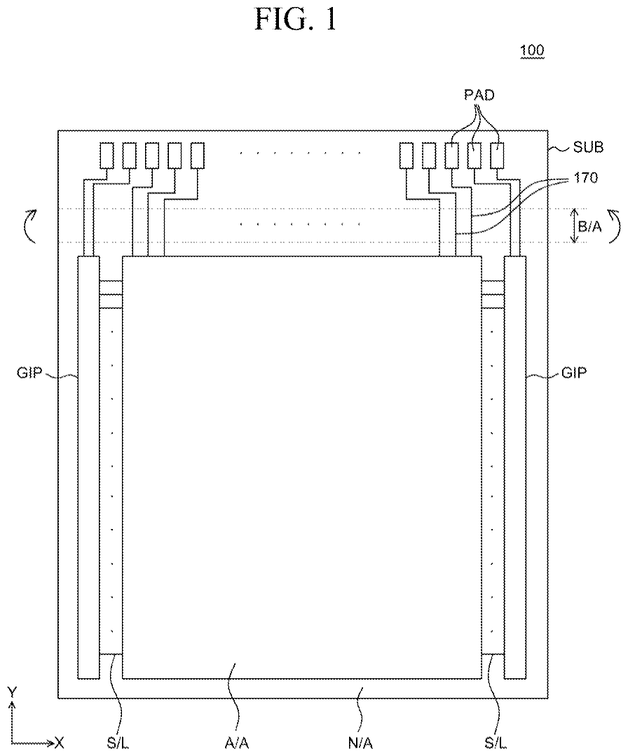

FIG. 1 is a plan view of a display device according to an exemplary aspect of the present disclosure. Specifically, a substrate SUB of a flexible electroluminescent display device 100 is in a state that is not bent.

Referring to FIG. 1, the flexible electroluminescent display device 100 includes an active area A/A in which pixels that actually emit light through thin film transistors and light emitting elements are disposed on a substrate SUB, and a non-active area N/A surrounding an outer edge of the active area A/A. The substrate SUB may be a flexible substrate that may be applied to bendable, foldable, flexible, and stretchable display devices.

In the non-active area N/A of the substrate SUB, circuits such as gate drivers GIP for driving the flexible electroluminescent display device 100 and various signal lines such as scan lines S/L and the like may be disposed. In addition, the circuit for driving the flexible electroluminescent display device 100 may be implemented as a gate in panel (GIP) on the substrate SUB or may be connected to the substrate SUB in a tape carrier package (TCP) or chip on film (COF) method.

Pads PAD are disposed on one side of the substrate SUB in the non-active area N/A. The pad PAD is a metal pattern that is bonded to an external module.

A bending area B/A may be formed by bending a portion of the non-active area N/A of the substrate SUB in a bending direction as indicated by the arrows shown in FIG. 1. The non-active area N/A of the substrate SUB is an area where lines and driving circuits for driving a screen are disposed, and is not an area where images are displayed, so it is unnecessary to be visible from an upper surface of the substrate SUB. Accordingly, by bending a portion of the non-active area N/A of the substrate SUB, it is possible to reduce a bezel area while securing an area for lines and driving circuits.

Various lines are formed on the substrate SUB. The lines may be formed in the active area A/A of the substrate SUB. Alternatively, circuit lines 170 formed in the non-active area N/A may be connected to driving circuits, gate drivers, data drivers and the like and transfer signals.

The circuit line 170 is formed of a conductive material and may be formed of a conductive material with excellent ductility that reduces occurrence of cracks when bending the substrate SUB. For example, the circuit line 170 may be formed of a conductive material with excellent ductility, such as gold (Au), silver (Ag) and aluminum (Al), may be formed of one of various conductive materials used in the active area A/A, and may also be composed of molybdenum (Mo), chromium (Cr), titanium (Ti), nickel (Ni), neodymium (Nd), copper (Cu), and an alloy of silver (Ag) and magnesium (Mg). In addition, the circuit line 170 may be composed of a multilayer structure including various conductive materials, for example, a three-layer structure of titanium (Ti)/aluminum (Al)/titanium (Ti), but is not limited thereto.

The circuit line 170 formed in the bending area B/A is subjected to a tensile force when it is bent. For example, the circuit line 170 extending in the same direction as the bending direction (indicated by the arrows shown in FIG. 1) on the substrate SUB is subjected to the greatest tensile force, and cracks may occur. If the cracks are severe, disconnection may occur. Accordingly, by forming at least a portion of the circuit line 170 disposed in an area including the bending area B/A to extend while having a bent portion including a concave portion CC and a convex portion CV, rather than forming the circuit line 170 to extend in the bending direction, it is possible to minimize the tensile force and thereby minimize the occurrence of cracks.

The circuit line 170 disposed in the area including the bending area B/A may be formed in various shapes, for example, a trapezoidal wave shape, a triangle wave shape, a sawtooth wave shape, a sinusoidal wave shape, an omega (Q) shape, or a rhombus shape.

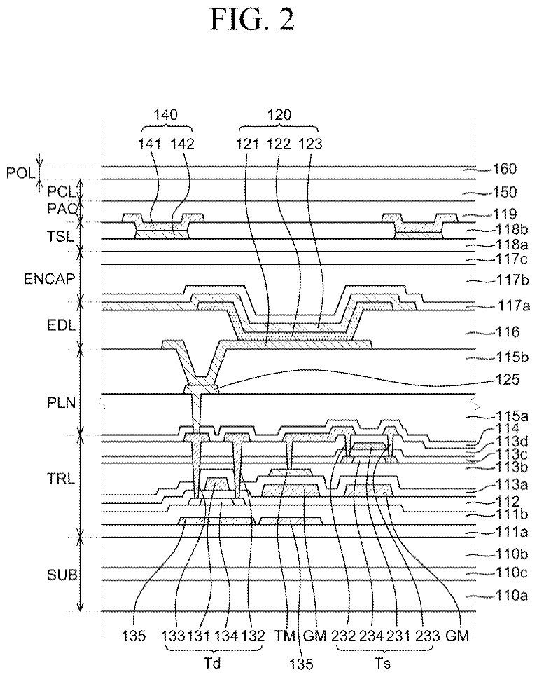

Hereinafter, a more detailed description of a cross-sectional structure of the active area A/A of the display device 100 will be provided with reference to FIG. 2.

FIG. 2 is a cross-sectional view of the display device according to an exemplary aspect of the present disclosure.

In the active area A/A, a transistor layer TRL may be disposed on the substrate SUB, and a planarization layer PLN may be disposed on the transistor layer TRL. In addition, a light emitting element layer EDL may be disposed on the planarization layer PLN, an encapsulation layer ENCAP may be disposed on the light emitting element layer EDL, a touch sensing layer TSL may be disposed on the encapsulation layer ENCAP, and a protective layer PAC may be disposed on the touch sensing layer TSL. In addition, an organic layer PCL may be disposed on the protective layer PAC, and a polarization layer POL may be disposed on the organic layer PCL.

The substrate SUB is a component to support various components included in the display device 100 and may be formed of an insulating material. The substrate SUB may include a first substrate 110a, a second substrate 110b, and an interlayer insulating layer 110c. The interlayer insulating layer 110c may be disposed between the first substrate 110a and the second substrate 110b. In this manner, moisture penetration may be prevented by configuring the substrate SUB with the first substrate 110a, the second substrate 110b, and the interlayer insulating layer 110c. For example, the first substrate 110a and the second substrate 110b may be polyimide (PI) substrates.

In the active area A/A, various patterns 131, 132, 133, 134, 231, 232, 233, and 234, various insulating layers 111a, 111b, 112, 113a, 113b, and 114, and various metal patterns TM, GM, and 135 for forming transistors such as a driving transistor Td and at least one switching transistor Ts, and at least one capacitor may be disposed in the transistor layer TRL.

Hereinafter, a stacked structure of the transistor layer TRL will be described in more detail.

A multi-buffer layer 111a may be disposed on the second substrate 110b, and an active buffer layer 111b may be disposed on the multi-buffer layer 111a.

A metal layer 135 may be disposed on the multi-buffer layer 111a.

Here, the metal layer 135 may function as a light shield and may also be referred to as a light blocking layer.

The active buffer layer 111b may be disposed on the metal layer 135.

A first active layer 134 of the driving transistor Td may be disposed on the active buffer layer 111b. For example, the first active layer 134 may be formed of polycrystalline silicon (p-Si), amorphous silicon (a-Si), or an oxide semiconductor, but is not limited thereto. Meanwhile, the driving transistor Td may be formed on the active buffer layer 111b and includes the first active layer 134, a first gate insulating layer 112 covering the first active layer 134, a first gate electrode 131 disposed on the first gate insulating layer 112, a first interlayer insulating layer 113a covering the first gate electrode 131, a second interlayer insulating layer 113b disposed on the first interlayer insulating layer 113a, a second gate insulating layer 113c disposed on the second interlayer insulating layer 113b, and a first source electrode 132 and a first drain electrode 133 disposed on the second gate insulating layer 113c.

The first gate insulating layer 112 may be disposed on the first active layer 134. The first gate insulating layer 112 may be formed of silicon oxide (SiOx), silicon nitride (SiNx), or a multilayer thereof.

In addition, the first gate electrode 131 of the driving transistor Td may be disposed on the first gate insulating layer 112. The first gate electrode 131 is disposed on the first gate insulating layer 112 to overlap the first active layer 134. The first gate electrode 131 may be formed of various conductive materials, such as magnesium (Mg), aluminum (Al), nickel (Ni), chromium (Cr), molybdenum (Mo), tungsten (W) and gold (Au) or an alloy thereof, but is not limited thereto.

A gate material layer GM may be disposed on the first gate insulating layer 112 at a location different from a location at which the driving transistor Td is formed.

The first interlayer insulating layer 113a may be disposed on the first gate electrode 131 and the gate material layer GM. The metal pattern TM may be disposed on the first interlayer insulating layer 113a. A second interlayer insulating layer 113b may be disposed to cover the metal pattern TM disposed on the first interlayer insulating layer 113a.

The second interlayer insulating layer 113b separates a second active layer 234 from the first active layer 134 and provides a base for forming the second active layer 234.

The second active layer 234 of the switching transistor Ts may be disposed on the second interlayer insulating layer 113b. For example, the second active layer 234 may be formed of polycrystalline silicon, amorphous silicon, or an oxide semiconductor, but is not limited thereto.

A second gate insulating layer 113c may be disposed on the second active layer 234. In addition, a second gate electrode 231 of the switching transistor Ts may be disposed on the second gate insulating layer 113c. The second gate electrode 231 is disposed on the second gate insulating layer 113c to overlap the second active layer 234.

The second gate insulating layer 113c covers the second active layer 234 of the switching transistor Ts. Since the second gate insulating layer 113c is formed on the second active layer 234, it is implemented as an inorganic layer. For example, the second gate insulating layer 113c may be silicon oxide (SiO2), silicon nitride (SiNx), or a multiple layer thereof.

The second gate electrode 231 is formed of a metal material. For example, the second gate electrode 231 may be a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but is not limited thereto.

Meanwhile, the switching transistor Ts may be formed on the second interlayer insulating layer 113b and includes the second active layer 234, the second gate insulating layer 113c covering the second active layer 234, the second gate electrode 231 disposed on the second gate insulating layer 113c, the second gate insulating layer 113c covering the second gate electrode 231, and a second source electrode 232 and a second drain electrode 233 disposed on the second gate insulating layer 113c.

The switching transistor Ts further includes the gate material layer GM that is located below the first interlayer insulating layer 113a and overlaps the second active layer 234. The gate material layer GM may secure reliability of the switching transistor Ts by blocking light incident onto the second active layer 234. The gate material layer GM may be formed of the same material as the first gate electrode 131 and may be formed on an upper surface of the first gate insulating layer 112. The gate material layer GM may be electrically connected to the second gate electrode 231 to form a dual gate. On a third interlayer insulating layer 113d, the first source electrode 132 and the first drain electrode 133 of the driving transistor Td and the second source electrode 232 and the second drain electrode 233 of the switching transistor Ts may be disposed.

The second source electrode 232 and the second drain electrode 233 may be simultaneously formed on the third interlayer insulating layer 113d along with the first source electrode 132 and the first drain electrode 133 and formed of the same material, thereby allowing for a reduction in the number of mask processes.

The first source electrode 132 and the first drain electrode 133 may be connected to one side and the other side of the first active layer 134, respectively, through contact holes provided in the third interlayer insulating layer 113d, the second gate insulating layer 113c, the second interlayer insulating layer 113b, the first interlayer insulating layer 113a, and the first gate insulating layer 112.

The second source electrode 232 and the second drain electrode 233 may be connected to one side and the other side of the second active layer 234, respectively, through contact holes provided in the third interlayer insulating layer 113d and the second gate insulating layer 113c.

The first source electrode 132 and the first drain electrode 133, and the second source electrode 232 and the second drain electrode 233 may be a single layer or multiple layers formed of various conductive materials, for example, magnesium (Mg), aluminum (Al), nickel (Ni), chromium (Cr), molybdenum (Mo), tungsten (W), gold (Au), or an alloy thereof, but the present disclosure is not limited thereto.

A portion of the first active layer 134 that overlaps the first gate electrode 131 is a channel region. One of the first source electrode 132 and the first drain electrode 133 is connected to one side of the channel region in the first active layer 134, and the other one thereof is connected to the other side of the channel region in the first active layer 134. The second active layer 234 may be configured in the same form as the first active layer 134, and when the second active layer 234 is implemented as an oxide semiconductor material, it includes an intrinsic second channel region that is not doped with impurities, and a second source region and a second drain region that are doped with impurities and conductorized.

A passivation layer 114 may be disposed on the first source electrode 132 and the first drain electrode 133, and the second source electrode 232 and the second drain electrode 233. The passivation layer 114 is to protect the driving transistor Td, and may be formed of an inorganic layer, for example, silicon oxide (SiOx), silicon nitride (SiNx), or a multiple layer thereof.

Meanwhile, a capacitor Cst may be implemented by disposing the gate material layer GM and the metal pattern TM on the first gate insulating layer 112 to overlap each other. The metal pattern TM may be a single layer or a multilayer formed of any one of, for example, molybdenum (Mo), aluminum (Al), chromium (Cr), gold (Au), titanium (Ti), nickel (Ni), neodymium (Nd), and copper (Cu), or an alloy thereof.

The capacitor Cst stores data voltages applied through data lines DL for a predetermined period of time and provides it to a light emitting element (ED) 120. The capacitor Cst includes two electrodes corresponding to each other and a dielectric material disposed therebetween. The first interlayer insulating layer 113a is located between the gate material layer GM and the metal pattern TM.

The gate material layer GM or the metal pattern TM in the capacitor Cst may be electrically connected to the second source electrode 232 or the second drain electrode 233 of the switching transistor Ts. However, the present disclosure is not limited thereto and a connection relationship of the capacitor Cst may be changed according to a pixel driving circuit.

In addition, the metal layer 135 may be disposed on the multi-buffer layer 111a to additionally overlap the gate material layer GM and the metal pattern TM to form a double capacitor Cst.

In an exemplary aspect of the present disclosure, at least one switching transistor Ts uses an oxide semiconductor as an active layer. A transistor using an oxide semiconductor as an active layer has an excellent leakage current blocking effect and is relatively inexpensive in manufacture costs compared to a transistor using polycrystalline silicon as an active layer. Accordingly, to reduce power consumption and lower manufacturing costs, a pixel circuit according to an exemplary aspect of the present disclosure includes a driving transistor or at least one switching transistor using an oxide semiconductor material.

All of transistors constituting the pixel circuit by including the driving transistor, may implement an active layer using an oxide semiconductor, or only some of the transistors may implement an active layer using an oxide semiconductor.

However, it is difficult to ensure reliability of transistors using oxide semiconductors, and transistors using polycrystalline silicon have a fast operation speed and excellent reliability. Thus, aspects of the present disclosure include both transistors using oxide semiconductors and transistors using polycrystalline silicon. However, the present disclosure is not limited thereto, and depending on a design, the pixel circuit may be configured by applying only transistors using oxide semiconductors or only transistors using polycrystalline silicon.

The planarization layer PLN may be located on the transistor layer TRL.

The planarization layer PLN may include a first planarization layer 115a and a second planarization layer 115b. The planarization layer PLN protects the driving transistor Td and planarizes an upper portion thereof.

The first planarization layer 115a may be disposed on the passivation layer 114.

A connection electrode 125 may be disposed on the first planarization layer 115a.

The connection electrode 125 may be connected to one of the first source electrode 132 and the first drain electrode 133 through a contact hole provided in the first planarization layer 115a.

The second planarization layer 115b may be disposed on the connection electrode 125.

The light emitting element layer EDL may be located on the second planarization layer 115b.

Hereinafter, a stacked structure of the light emitting element layer EDL will be described in detail.

An anode 121 may be disposed on the second planarization layer 115b. In this case, the anode 121 may be electrically connected to the connection electrode 125 through a contact hole provided in the second planarization layer 115b. The anode 121 may be formed of a metallic material.

When the display device 100 is a top emission type in which light emitted from the light emitting element (ED) 120 is emitted upwardly of the substrate SUB on which the light emitting element (ED) 120 is disposed, the anode 121 may further include a transparent conductive layer and a reflective layer on the transparent conductive layer. The transparent conductive layer may be formed of, for example, a transparent conductive oxide such as ITO and IZO, and the reflective layer may be formed of, for example, silver (Ag), aluminum (Al), gold (Au), molybdenum (Mo), tungsten (W), chromium (Cr), or alloys thereof.

A bank 116 may be disposed to cover the anode 121. A portion of the bank 116 corresponding to an emission area of a sub-pixel may be open. A portion of the anode 121 may be exposed through the open portion of the bank 116 (hereinafter, referred to as an open area). In this case, the bank 116 may be formed of an inorganic insulating material such as silicon nitride (SiNx) and silicon oxide (SiOx), or an organic insulating material such as benzocyclobutene-based resin, acrylic resin, and imide-based resin, but is limited thereto.

Although not shown, spacers may be further located on the bank 116. The spacer may be formed of the same material as the bank 116.

A light emitting layer 122 may be disposed in the open portion of the bank 116 and around the open area of the bank 116. Accordingly, the light emitting layer 122 may be disposed on the anode 121 that is exposed through the open area of the bank 116.

A cathode 123 may be disposed on the light emitting layer 122.

The light emitting element (ED) 120 may be formed by the anode 121, the light emitting layer 122, and the cathode 123. The light emitting layer 122 may include a plurality of organic layers.

The encapsulation layer ENCAP may be located on the light emitting element layer EDL described above.

The encapsulation layer ENCAP may have a single-layer structure or a multilayer structure. For example, the encapsulation layer ENCAP may include a first encapsulation layer 117a, a second encapsulation layer 117b, and a third encapsulation layer 117c.

In this case, the first encapsulation layer 117a and the third encapsulation layer 117c may be formed of an inorganic layer, and the second encapsulation layer 117b may be formed of an organic layer. Among the first encapsulation layer 117a, the second encapsulation layer 117b, and the third encapsulation layer 117c, the second encapsulation layer 117b is thickest and may serve as a planarization layer.

The first encapsulation layer 117a may be disposed on the cathode 123 and may be disposed closest to the light emitting element (ED) 120. The first encapsulation layer 117a may be formed of an inorganic insulating material capable of low-temperature deposition. For example, the first encapsulation layer 117a may be formed of silicon nitride (SiNx), silicon oxide (SiOx), silicon oxynitride (SiON), or aluminum oxide (Al₂O₃). Since the first encapsulation layer 117a is deposited in a low-temperature atmosphere, it is possible to prevent damage to the light emitting layer 122, which contains an organic material vulnerable to a high-temperature atmosphere, during a deposition process.

The second encapsulation layer 117b may be formed to have an area smaller than the first encapsulation layer 117a. In this case, the second encapsulation layer 117b may be formed to expose both ends of the first encapsulation layer 117a. The second encapsulation layer 117b may serve as a buffer to alleviate stress between respective layers due to bending of the flexible display device and may serve to enhance planarization performance.

For example, the second encapsulation layer 117b may be formed of an organic insulating material such as acrylic resin, epoxy resin, polyimide, polyethylene, and silicon oxycarbon (SiOC). For example, the second encapsulation layer 117b may be formed using an inkjet method, but is not limited thereto.

The second encapsulation layer 117b including an organic material may be located only on an inner surface of a dam portion disposed at an innermost position among first dam portions DAM1. That is, the second encapsulation layer 117b may not exist on all of the dam portions. Alternatively, the second encapsulation layer 117b including an organic material may be located on an upper portion of at least the innermost dam portion among the first dam portions DAM1. That is, the second encapsulation layer 117b may be located to extend up to the upper portion of the innermost dam portion among the first dam portions DAM1. Alternatively, the second encapsulation layer 117b may pass through the upper portion of the innermost dam portion among the first dam portions DAM1 and be located to extend to an upper portion of an outermost dam portion among the first dam portions DAM1.

The third encapsulation layer 117c may be formed on an upper portion of the substrate SUB over which the second encapsulation layer 117b is formed so to cover an upper surface and side surfaces of each of the second encapsulation layer 117b and the first encapsulation layer 117a. In this case, the third encapsulation layer 117c may minimize or block external moisture or oxygen from penetrating into the first encapsulation layer 117a and the second encapsulation layer 117b. For example, the third encapsulation layer 117c may be formed of an inorganic insulating material such as silicon nitride (SiNx), silicon oxide (SiOx), silicon oxynitride (SiON), and aluminum oxide (Al₂O₃).

The touch sensing layer TSL may be disposed on the encapsulation layer ENCAP described above.

The touch sensing layer TSL may include a touch buffer layer 118a disposed on the encapsulation layer ENCAP, a touch electrode 140 disposed on the touch buffer layer 118a, and a touch interlayer insulating layer 118b.

The touch electrode 140 may include a touch sensor metal 141 and a bridge metal 142 that are located in different layers. The touch interlayer insulating layer 118b may be disposed between the touch sensor metal 141 and the bridge metal 142.

For example, the touch sensor metal 141 may include a first touch sensor metal, a second touch sensor metal, and a third touch sensor metal that are disposed adjacent to each other. The first touch sensor metal and the second touch sensor metal are electrically connected to each other, but when the third touch sensor metal is between the first touch sensor metal and the second touch sensor metal, the first touch sensor metal and the second touch sensor metal may be electrically connected through the bridge metal 142 that is disposed in a layer different therefrom. The bridge metal 142 may be insulated from the third touch sensor metal by the touch interlayer insulating layer 118b.

When forming the touch sensing layer TSL, a chemical solution (developer or etchant or the like) used in a process or moisture from the outside may be generated. By disposing the touch buffer layer 118a and disposing the touch sensing layer TSL thereon, it is possible to prevent a chemical solution or moisture or the like from penetrating into the light emitting layer 122 including an organic material during a manufacture of the touch sensing layer TSL. Accordingly, the touch buffer layer 118a may prevent damage to the light emitting layer 122, which is vulnerable to a chemical solution or moisture.

The touch buffer layer 118a may be formed of an organic insulating material that may be formed at a certain temperature (e.g., a low temperature of 100° C. or less) and has a low dielectric constant of 1 to 3 to prevent damage to the light emitting layer 122 including an organic material vulnerable to high temperatures. For example, the touch buffer layer 118a may be formed of an acrylic-based, epoxy-based, or siloxane-based material. As the flexible display device is bent, the encapsulation layer ENCAP may be damaged, and the touch sensor metal 141 located on the touch buffer layer 118a may be broken. Even if the flexible display device is bent, the touch buffer layer 118a that is formed of an organic insulating material and has a planarization performance may prevent damage to the encapsulation layer ENCAP and cracking of the metals 141 and 142 constituting the touch electrode 140.

The protective layer (PAC) 119 may be disposed to cover the touch electrode 140. The protective layer 119 may be formed of an organic insulating layer.

The organic material layer (PCL) 150 is disposed to cover the protective layer 119.

When only the protective layer 119 formed of an organic insulating layer is disposed on an uppermost layer of the display device 100, a step caused by the touch sensing layer TSL disposed below the protective layer 119 may not be completely supplemented only by the protective layer 119. As a result, a defect may occur in which stains caused by the touch electrode 140 are visible to a user.

By adding the organic material layer 150 formed of an organic insulating layer on the protective layer 119, visibility of the display device 100 may be improved by preventing a step in the uppermost layer of the display device 100.

The organic material layer 150 may be formed of the same material as the second encapsulation layer 117b of the encapsulation layer ENCAP, and may be formed of an organic insulating material, such as acrylic resin, epoxy resin, polyimide, polyethylene, and silicon oxycarbon (SiOC). The organic material layer 150 may be formed through an inkjet method, but is not limited thereto.

The polarization layer (POL) 160 is disposed on the organic layer 150.

The polarization layer 160 suppresses reflection of external light on the active area A/A of the substrate SUB. When the display device 100 is used outside, external natural light is introduced and may be reflected by the reflective layer included in the anode 121 of the light emitting element, or may be reflected by an electrode formed of a metal disposed at a bottom of the light emitting element (ED) 120. An image of the display device 100 may not be visible due to the reflected light described above. The polarization layer 160 polarizes light introduced from the outside in a specific direction and prevents the reflected light from being emitted to the outside of the display device 100 again.

Although not shown, a cover glass may be adhered to the polarization layer 160 using an adhesive layer. The adhesive layer may serve to bond respective components of the display device 100 to each other, and for example, may be formed using an optically transparent display adhesive such as a pressure-sensitive adhesive, an optical clear adhesive (OCR), an optical clear resin (OCR) or the like, but is not limited thereto.

The cover glass may protect components of the display device 100 from external impacts and prevent damage such as scratches.

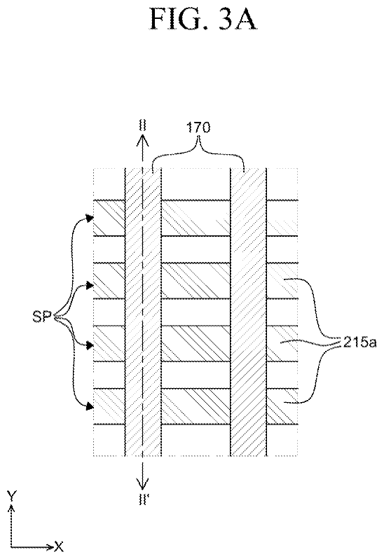

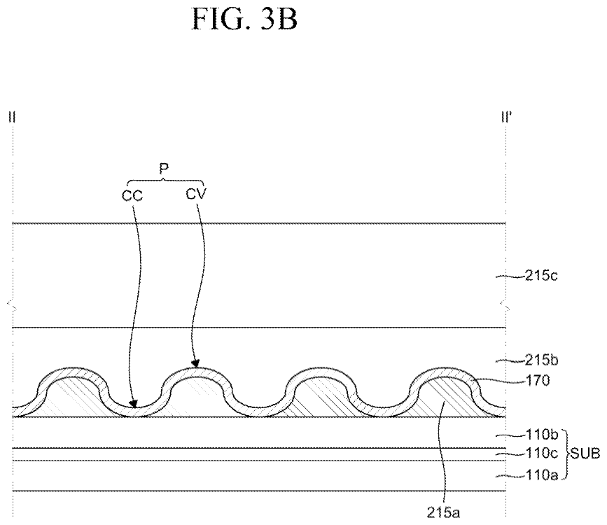

Referring to FIG. 1, FIG. 3A and FIG. 3B, the display device 100 may include the active area A/A including the plurality of pixels and the non-active area N/A adjacent to the active area A/A. The non-active area N/A may include a flexible substrate SUB including the bending area B/A bent in the first direction. The display device 100 may include a pattern unit P disposed on the flexible substrate SUB of the bending area B/A and including concave portions CC and convex portions CV. The display device 100 may have a structure including a plurality of lines, for example, circuit lines. The concave portion CC and the convex portion CV may be formed of an insulating layer, and a curved structure may be formed by forming a plurality of lines on the insulating layer, and a crack prevention effect may be obtained through the curved structure.

FIGS. 3A and 3B are detailed structures of a bending area according to an exemplary aspect of the present disclosure.

Hereinafter, a more detailed description of detailed planar and cross-sectional structures of the bending area B/A of the display device 100 will be provided with reference to FIGS. 3A and 3B.

Referring to FIG. 3A, the circuit lines 170 are formed to extend in the first direction (e.g., Y-axis direction) which is a direction extending from the active area A/A to the bending area B/A. Along the first direction, a first insulating layer (or stress reducing part) 215a has concave portions CC and convex portions CV. The concave portions CC and the convex portions CV are repeatedly disposed along the first direction. The plurality of respective circuit lines 170 may be formed at intervals in a second direction (e.g., X-axis direction), which is a direction different from (e.g., perpendicular to) the first direction (e.g., bending direction). The plurality of circuit lines 170 may extend in the first direction along upper surfaces of the concave portions CC and the convex portions CV.

At least one or more insulating layers may be disposed in the bending area B/A. The insulating layers may have the pattern unit P, and the pattern unit P may be repeatedly disposed along the first direction in which the circuit lines 170 extend. The insulating layers may have at least one or more pattern units P. The insulating layers may have at least one or more grooves.

The pattern unit P may be formed in a groove structure. The insulating layers may have at least one or more grooves. The insulating layers may include first, second, and third insulating layers 215a, 215b, and 215c. The insulating layers may be formed by extending at least one layer of the active buffer layer 111b, the multi-buffer layer 111a, the planarization layer PLN, the encapsulation layer ENCAP, the protective layer PAC, the organic material layer PCL, the interlayer insulating layer 110c, various insulating layers 111a, 111b, 112, 113a, 113b, and 114, and a micro-coating layer 750, which are components formed in the active area A/A. The first, second, and third insulating layers 215a, 215b, and 215c may be formed by extending at least one layer of the active buffer layer 111b, the multi-buffer layer 111a, the planarization layer PLN, the encapsulation layer ENCAP, the protective layer PAC, the organic material layer PCL, the interlayer insulating layer 110c, various insulating layers 111a, 111b, 112, 113a, 113b, and 114, and the micro-coating layer 750, which are components formed in the active area A/A. The insulating layers and the first, second, and third insulating layers may be an organic material or an inorganic material. Examples of the inorganic material may include silicon nitride (SiNx), silicon oxide (SiOx), silicon oxynitride (SiON), or aluminum oxide (Al₂O₃).

The pattern unit P may include at least one sub-pattern SP. The pattern unit P may include a plurality of sub-patterns SP that are spaced apart from each other and repeatedly disposed in the first direction. The plurality of sub-patterns SP may have a shape in which they extend and elongate in the second direction perpendicular to the first direction.

In an exemplary aspect of the present disclosure, thin film transistors may be formed on the flexible substrate corresponding to the active area. The first planarization layer may be disposed on the thin film transistor. The connection electrode connected to the thin film transistor may be disposed on the first planarization layer. The second planarization layer may be disposed on the connection electrode. A display unit including the light emitting element that is disposed on the second planarization layer and electrically connected to the connection electrode is further included, and the first planarization layer and the second planarization layer may have a structure extending from the active area to the bending area.

Referring to FIG. 3B, the substrate SUB may be a flexible substrate. The substrate SUB may be formed of a plurality of layers including the first substrate 110a and the second substrate 110b, and may be formed of a single layer. The interlayer insulating layer 110c may be disposed between the first substrate 110a and the second substrate 110b. For example, the first substrate 110a and the second substrate 110b may be polyimide (PI) substrates. The first insulating layer 215a may be disposed on the substrate SUB.

The first insulating layer 215a may include the pattern unit P. The pattern unit P may include a groove. Each of a lower surface of the concave portion CC and the upper surface of the convex portion CV of the first insulating layer may have a round shape. An inclination of the pattern unit P may continuously change from the concave portion CC to the convex portion CV in a cross-section. The circuit lines 170 may be formed along the concave portions CC and convex portions CV on the first insulating layer 215a. The second insulating layer (or circuit line protecting layer) 215b may be disposed on the circuit line 170 and the third insulating layer 215c may be disposed on the second insulating layer 215b.

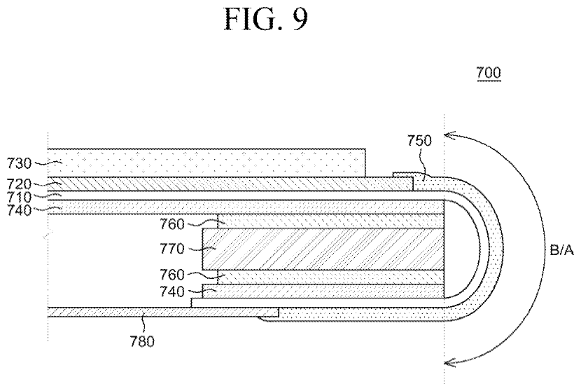

The first, second, and third insulating layers 215a, 215b, and 215c formed on the substrate SUB may include a configuration in which an inorganic or organic insulating layer in the active area A/A extends. As examples of the first, second, and third insulating layers 215a, 215b, and 215c, at least one layer of the active buffer layer 111b, the multi-buffer layer 111a, the planarization layer PLN, the encapsulation layer ENCAP, the protective layer PAC, the organic material layer PCL, the interlayer insulating layer 110c, the various insulating layers 111a, 111b, 112, 113a, 113b, and 114, and the micro-coating layer 750 (in FIG. 9) may be extended and formed. The third insulating layer 215c may be the micro-coating layer 750, and the micro-coating layer 750 may not be disposed in the active area A/A but may be disposed only in the bending area B/A. The active area A/A may not include the micro-coating layer 750 but may include the bending area B/A.

The circuit lines 170 may extend to the metal layer 135, the first gate electrode 131, the first source electrode 132 and the first drain electrode 133, the metal pattern TM, the second gate electrode 231, and the second source electrode 232 and the second drain electrode 233, and may be formed in the bending area and be electrically connected thereto. The circuit lines 170 may be patterned together with the metal layer 135, the first gate electrode 131, the first source electrode 132 and the first drain electrode 133, the metal pattern TM, the second gate electrode 231, and the second source electrode 232 and the second drain electrode 233, or may be formed on the same layer through the same process. The circuit lines 170 may be electrically connected to the first active layer 134 and the second active layer 234. The circuit lines 170 may be formed of various conductive materials, such as magnesium (Mg), aluminum (Al), nickel (Ni), chromium (Cr), molybdenum (Mo), tungsten (W), and gold (Au), or an alloy thereof, but the present disclosure is not limited thereto.

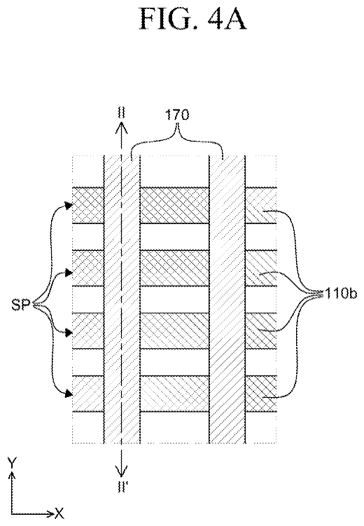

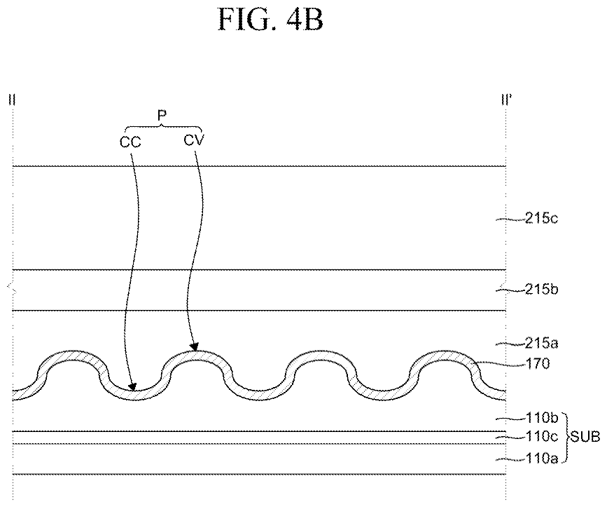

FIGS. 4A and 4B are detailed structures of a bending area according to an exemplary aspect of the present disclosure.

Hereinafter, a more detailed description of detailed planar and cross-sectional structures of the bending area B/A of the display device 100 will be provided with reference to FIGS. 4A and 4B.

Referring to FIG. 4A, the circuit lines 170 are formed to extend in the first direction which is a direction extending from the active area A/A to the bending area B/A. Along the first direction, the second substrate 110b has concave portions CC and convex portions CV. The concave portions CC and the convex portions CV are repeatedly disposed along the first direction. The plurality of respective circuit lines 170 may be formed at intervals in the second direction, which is a direction perpendicular to the first direction. The plurality of circuit lines 170 may extend in the first direction along the upper surfaces of the concave portions CC and the convex portions CV.

At least one or more substrates SUB may be disposed in the bending area B/A. The substrate SUB may have a pattern unit P, and the pattern unit P may be repeatedly disposed along the first direction in which the circuit line 170 extends. The substrate SUB may have at least one or more pattern units P. The substrate SUB may have at least one or more grooves.

The pattern unit P may be formed in a groove structure. The substrate SUB may have at least one or more grooves. The substrate SUB may include the first and second substrates 110a and 110b and the interlayer insulating layer 110c. The interlayer insulating layer 110c may be an organic material or an inorganic material. Examples of the inorganic material include silicon nitride (SiNx), silicon oxide (SiOx), silicon oxynitride (SiON), or aluminum oxide (Al₂O₃).

The pattern unit P may include at least one sub-pattern SP. The pattern unit P may include a plurality of sub-patterns SP that are spaced apart from each other and repeatedly disposed in the first direction. The plurality of sub-patterns SP may have a shape in which they extend and elongate in the second direction perpendicular to the first direction.

The flexible substrate may include a first polyimide layer, an inorganic insulating layer on the first polyimide layer, and a second polyimide layer on the inorganic insulating layer, and the pattern unit P may be formed of the second polyimide layer.

Referring to FIG. 4B, the substrate SUB may be a flexible substrate. The substrate may be formed of a plurality of layers including the first substrate 110a and the second substrate 110b, or may be formed of a single layer thereof. The interlayer insulating layer 110c may be disposed between the first substrate 110a and the second substrate 110b. For example, the first substrate 110a and the second substrate 110b may be polyimide (PI) substrates. The substrate SUB may include a pattern unit P. The second substrate 110b may include the pattern unit P. The pattern unit P may include a groove. Each of the lower surface of the concave portion CC and the upper surface of the convex portion CV of the second substrate 110b may have a round shape. An inclination of the pattern unit P may continuously change from the concave portion CC to the convex portion CV in a cross-section. The circuit lines 170 may be formed along the concave portion CC and convex portion CV on the second substrate 110b. The first insulating layer 215a may be disposed on the circuit line 170 and the second insulating layer 215b may be disposed on the first insulating layer 215a. The third insulating layer 215c may be disposed on the second insulating layer 215b.

At least a portion of the plurality of lines may be disposed to contact the flexible substrate in the groove thereof, or may be disposed to contact another insulating layer disposed between the flexible substrate and at least one insulating layer. The pattern unit P may be formed of the first planarization layer, and the second planarization layer may be disposed on the plurality of lines. The pattern unit P may be formed of the first planarization layer and the second planarization layer.

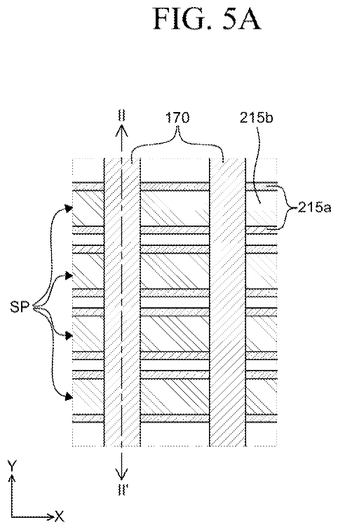

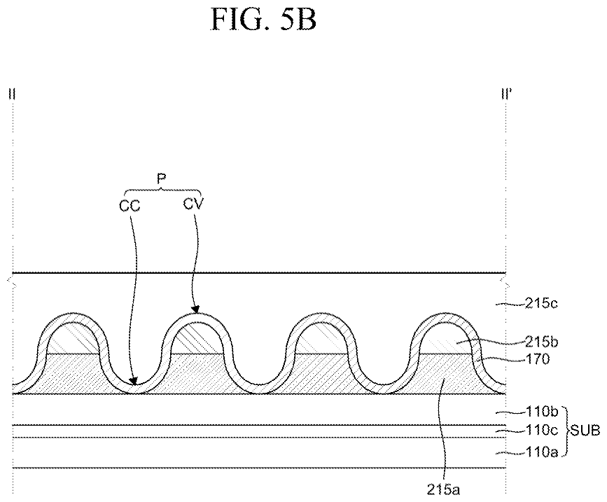

FIGS. 5A and 5B are other detailed structures of a bending area according to an exemplary aspect of the present disclosure.

Hereinafter, a more detailed description of detailed planar and cross-sectional structures of the bending area B/A of the display device 100 will be provided with reference to FIGS. 5A and 5B.

Referring to FIG. 5A, the circuit lines 170 are formed to extend in the first direction which is a direction extending from the active area A/A to the bending area B/A. Along the first direction, the second insulating layer 215b has concave portions CC and convex portions CV. The second insulating layer 215b is formed on the first insulating layer 215a, and the circuit line 170 extends to overlap and contact the first and second insulating layers 215a and 215b. The concave portions CC and the convex portions CV formed of the first and second insulating layers 215a and 215b are repeatedly disposed along the first direction. The plurality of respective circuit lines 170 may be formed at intervals in the second direction, which is a direction perpendicular to the first direction. The plurality of circuit lines 170 may extend in the first direction along the upper surfaces of the concave portions CC and the convex portions CV formed of the first and second insulating layers 215a and 215b.

The pattern unit P may be formed in a groove structure. The insulating layers may have at least one or more grooves. The insulating layers may include the first and second insulating layers 215a and 215b. The groove portion may be formed in the first insulating layer to form the concave portion CC and the convex portion CV. Considering a structure in a plan view, patterns may be repeatedly formed in an order of the first insulating layer 215a, the second insulating layer 215b, the first insulating layer 215a, and the groove in the first direction.

Referring to FIG. 5B, the substrate SUB may be a flexible substrate. The substrate may be formed of a plurality of layers including the first substrate 110a and the second substrate 110b, or may be formed of a single layer thereof. The interlayer insulating layer 110c may be disposed between the first substrate 110a and the second substrate 110b. For example, the first substrate 110a and the second substrate 110b may be polyimide (PI) substrates. The first insulating layer 215a and the second insulating layer 215b may be disposed on the substrate.

The first insulating layer 215a and the second insulating layer 215b may include a pattern unit P. The pattern unit P may include a groove. The lower surface of the concave portion CC is formed in the first insulating layer 215a, and the upper surface of the convex portion CV is formed in the second insulating layer 215b, so that each of the lower surface of the concave portion CC and the upper surface of the convex portion CV may have a round shape. The inclination of the pattern unit P may continuously change from the concave portion CC to the convex portion CV in a cross-section. The circuit line 170 may be formed along the concave portions CC and convex portions CV on the first insulating layer 215a and the second insulating layer 215b. Both the first insulating layer 215a and the second insulating layer 215b may be disposed below the circuit line 170, and the third insulating layer 215c may be disposed on the circuit line 170.

The pattern unit P may be formed of the first insulating layer 215a and the second insulating layer 215b. The pattern unit P may include at least one sub-pattern. The pattern unit P may include a plurality of sub-patterns SP that are spaced apart from each other and repeatedly disposed in the first direction. The plurality of sub-patterns SP may have a shape in which they extend and elongate in the second direction perpendicular to the first direction.

The first insulating layer 215a and the second insulating layer 215b constituting the pattern unit P may be configured as the planarization layer PLN extending from the active area A/A, and specifically, the first insulating layer 215a and the second insulating layer 215b may be configured as the first planarization layer and the second planarization layer.

The pattern unit P may be formed of the first planarization layer 115a and the second planarization layer 115b, and the pattern unit P may be disposed below a plurality of lines.

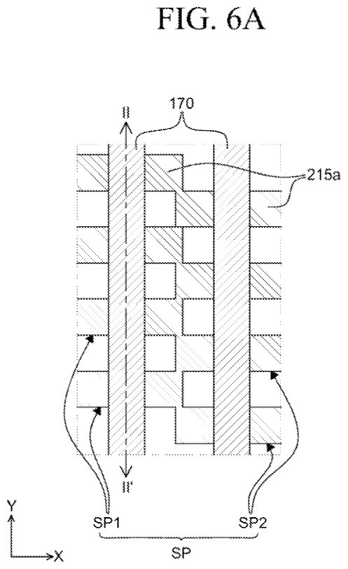

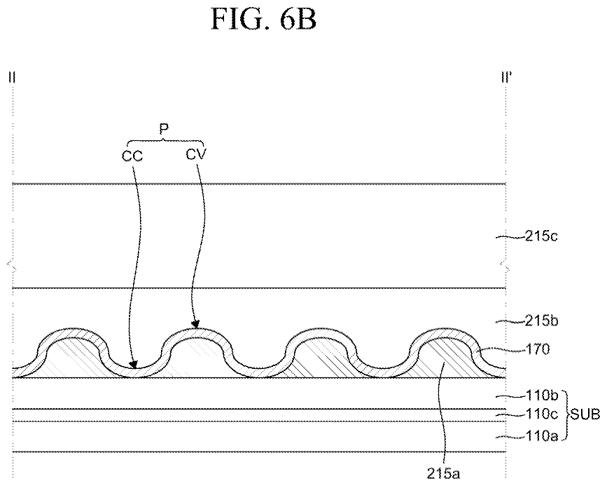

FIGS. 6A and 6B are still other detailed structures of a bending area according to an exemplary aspect of the present disclosure.

Hereinafter, a more detailed description of detailed planar and cross-sectional structures of the bending area B/A of the display device 100 will be provided with reference to FIGS. 6A and 6B.

Referring to FIG. 6A, the circuit lines 170 are formed to extend in the first direction, which is a direction extending from the active area A/A to the bending area B/A. Along the first direction, the first insulating layer 215a may have concave portions CC and convex portions CV. The concave portions CC and the convex portions CV are repeatedly disposed along the first direction. The plurality of respective circuit lines 170 may be formed at intervals in the second direction, which is a direction perpendicular to the first direction. The plurality of circuit lines 170 may extend in the first direction along the upper surfaces of the concave portions CC and the convex portions CV. At least one or more insulating layers may be disposed in the bending area B/A. The insulating layers may have a pattern unit P, and the pattern unit P may be repeatedly disposed along the first direction in which the circuit line 170 extends. The insulating layer may have at least one or more pattern units P. The insulating layer may have at least one or more grooves. The pattern unit P may be formed in a groove structure. The insulating layers may have at least one or more grooves. The insulating layers may include the first, second, and third insulating layers 215a, 215b, and 215c.

The pattern unit P may include at least one sub-pattern SP. The plurality of sub-patterns SP may be shifted in the first direction by a predetermined distance and sequentially disposed in the second direction perpendicular to the first direction.

Specifically, the plurality of sub-patterns SP may include a plurality of first sub-patterns SP1 disposed repeatedly in the first direction, and a plurality of second sub-patterns SP2 disposed adjacent in the second direction perpendicular to the first direction based on the first sub-patterns SP1 and repeatedly disposed in the first direction. Accordingly, the plurality of sub-patterns SP may include first grooves and the first sub-pattern SP1, and may include second grooves and the second sub-patterns. The second sub-pattern SP2 may be disposed on a side surface of the first groove and the second sub-pattern SP2 may be disposed on a side surface of the first sub-pattern SP1.

In this case, at least one corner of the first sub-pattern SP1 may be connected to at least one corner of the second sub-pattern SP2.

Referring to FIG. 6B, the substrate SUB may be a flexible substrate. The substrate may be formed of a plurality of layers including the first substrate 110a and the second substrate 110b, or may be formed of a single layer thereof. The interlayer insulating layer 110c may be disposed between the first substrate 110a and the second substrate 110b. For example, the first substrate 110a and the second substrate 110b may be polyimide (PI) substrates. The first insulating layer 215a may be disposed on the substrate.

The first insulating layer 215a may include a pattern unit P. The pattern unit P may include a groove. Each of the lower surface of the concave portion and the upper surface of the convex portion of the first insulating layer may have a round shape. The inclination of the pattern unit P may continuously change from the concave portion to the convex portion in a cross-section. The circuit line 170 may be formed along the concave portions CC and convex portions CV on the first insulating layer 215a. The second insulating layer 215b may be disposed on the circuit line 170 and the third insulating layer 215c may be disposed on the second insulating layer 215b.

The first, second, and third insulating layers 215a, 215b, and 215c formed on the substrate may include a configuration in which an inorganic or organic insulating layer in the active area A/A extends. As examples of the first, second, and third insulating layers 215a, 215b, and 215c, at least one layer of the active buffer layer 111b, the multi-buffer layer 111a, the planarization layer PLN, the encapsulation layer ENCAP, the protective layer PAC, the organic material layer PCL, the interlayer insulating layer 110c, the various insulating layers 111a, 111b, 112, 113a, 113b, and 114, and the micro-coating layer 750 may be extended and formed. The third insulating layer 215c may be the micro-coating layer 750, and the micro-coating layer 750 may not be disposed in the active area A/A but may be disposed only in the bending area B/A. The active area A/A may not include the micro-coating layer 750 but may include the bending area B/A.

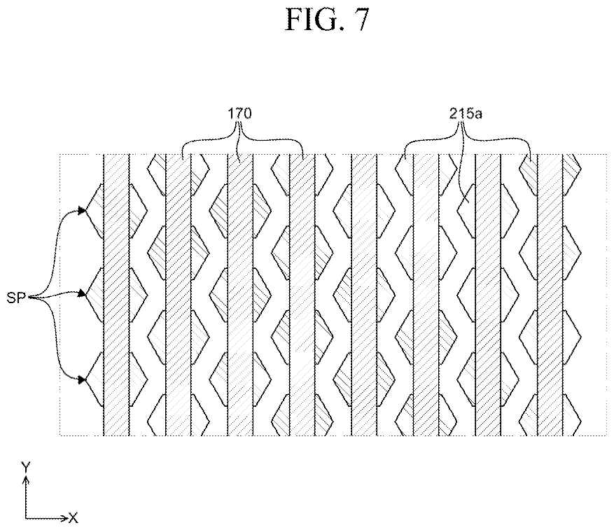

FIG. 7 is a plan view of still another detailed structure of a bending area according to an exemplary aspect of the present disclosure.

Hereinafter, a more detailed description of a structure of various pattern aspects for a detailed plane of the bending area B/A of the display device 100 will be provided with reference to FIG. 7.

Referring to FIG. 7, the pattern unit P may include at least one sub-pattern SB. The pattern unit P may include a plurality of sub-patterns SP that are spaced apart from each other and repeatedly disposed in the first direction and the second direction perpendicular to the first direction. Each of the plurality of sub-patterns SP may have a circular shape, a quadrangular shape, a hexagonal shape, an octagonal shape, a polygonal shape with rounded corners, or a polygonal shape with cut corners, in a plan view. The plurality of sub-patterns may be shifted in the first direction by a predetermined distance and sequentially disposed in the second direction perpendicular to the first direction. The first pattern unit P may include a first sub-pattern and a third sub-pattern, and the second pattern unit P may include a second sub-pattern and a fourth sub-pattern. The first sub-pattern and the third sub-pattern may be disposed along the first direction. The second sub-pattern and the fourth sub-pattern may be disposed along the first direction. The second sub-pattern may be shifted in the first direction by a predetermined distance based on the first sub-pattern and continuously disposed in the second direction perpendicular to the first direction. The fourth sub-pattern may be shifted in the first direction by a predetermined distance based on the third sub-pattern and disposed continuously in the second direction perpendicular to the first direction.

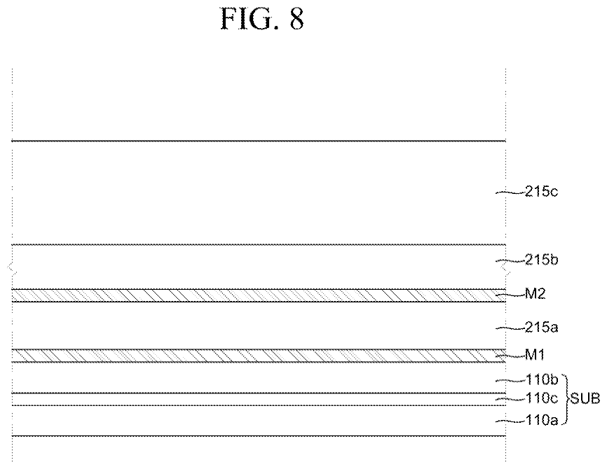

FIG. 8 is a cross-sectional view of a detailed structure of a bending area according to an exemplary aspect of the present disclosure.

Hereinafter, a more detailed description of detailed planar and cross-sectional structures of the bending area B/A of the display device 100 will be provided with reference to FIG. 8.

Referring to FIG. 8, the substrate SUB may be a flexible substrate. The substrate may be formed of a plurality of layers including the first substrate 110a and the second substrate 110b, or may be formed of a single layer thereof. The interlayer insulating layer 110c may be disposed between the first substrate 110a and the second substrate 110b. For example, the first substrate 110a and the second substrate 110b may be polyimide (PI) substrates. The first insulating layer 215a may be disposed on the substrate.

On the substrate, a first metal line M1 may extend from the active area A/A and be disposed in the bending area B/A, and the first insulating layer 215a may be formed on the first metal line M1. A second metal line M2 may extend from the active area A/A and be disposed in the bending area B/A on the first insulating layer 215a. The second insulating layer 215b may be disposed on the second metal line M2. The third insulating layer 215c may be formed on the second insulating layer 215b.

According to another exemplary aspect not shown in the drawings, the first insulating layer 215a may be disposed on the substrate and the first metal line M1 may be disposed on the first insulating layer 215a. The second insulating layer 215b may be disposed on the first metal line M1 and the second metal line M2 may be disposed on the second insulating layer 215b. The third insulating layer 215c may be disposed on the second metal line M2.

The first, second, and third insulating layers 215a, 215b, and 215c formed on the substrate may include a configuration in which an inorganic or organic insulating layer in the active area A/A extends. As examples of the first, second, and third insulating layers 215a, 215b, and 215c, at least one layer of the active buffer layer 111b, the multi-buffer layer 111a, the planarization layer PLN, the encapsulation layer ENCAP, the protective layer PAC, the organic material layer PCL, the interlayer insulating layer 110c, the various insulating layers 111a, 111b, 112, 113a, 113b, and 114, and the micro-coating layer 750 may be extended and formed. The third insulating layer 215c may be the micro-coating layer 750, and the micro-coating layer 750 may not be disposed in the active area A/A but may be disposed only in the bending area B/A. The active area A/A may not include the micro-coating layer 750 but may include the bending area B/A.

The first metal line M1 and the second metal line M2 may include the circuit line 170. The first metal line M1 and the second metal line M2 may extend to the metal layer 135, the first gate electrode 131, the first source electrode 132 and the first drain electrode 133, the metal pattern TM, the second gate electrode 231, and the second source electrode 232 and the second drain electrode 233, and may be formed in the bending area and be electrically connected thereto. The first metal line M1 and the second metal line M2 may be patterned together with the metal layer 135, the first gate electrode 131, the first source electrode 132 and the first drain electrode 133, the metal pattern TM, the second gate electrode 231, and the second source electrode 232 and the second drain electrode 233, or may be formed on the same layer through the same process. The first metal line M1 and the second metal line M2 may be electrically connected to the first active layer 134 and the second active layer 234.

Through structures of FIGS. 3 to 8, the display device has effects of reducing damage due to stress caused by bending of bent lines formed on the concave portion CC and the convex portion CV in the bending area by forming patterns on the insulating layer formed under the lines. The display device has effects of reducing stress of lines in the bending area due to variations in a neutral plane that may occur due to process deviation.

FIG. 9 is a cross-sectional view of a bending area of a display device according to an exemplary aspect of the present disclosure.

Referring to FIG. 9, a barrier film 720 is disposed on a flexible substrate 710. The barrier film 720 is a component for protecting various components of a flexible electroluminescent display device 700, and may be disposed to correspond to at least the active area A/A of the flexible electroluminescent display device 700.

For example, the barrier film 720 may be formed of an adhesive material, and the adhesive material may be a heat-curing or natural-curing adhesive, or may be formed of a material such as PSA (pressure sensitive adhesive), thereby serving to fix a polarizing plate 730 onto the barrier film 720.

The polarizing plate 730 disposed on the barrier film 720 suppresses reflection of external light on the active area A/A. When the display device 700 is used outside, external natural light may be introduced and be reflected by a reflector included in the anode of an electroluminescent device or by an electrode formed of metal disposed below an organic light emitting device. An image of the display device 700 may not be clearly visible due to the reflected light. The polarizing plate 730 polarizes light introduced from the outside in a specific direction and prevents the reflected light from being emitted to the outside of the display device 700 again. The polarizing plate 730 may be disposed on the active area A/A, but is not limited thereto.

The polarizing plate 730 may be a polarizing plate composed of a polarizer and a protective film that protects it, or may be formed by coating a polarizing material for flexibility.

A cover glass CG, which protects an exterior of the display device 700, may be disposed by placing an adhesive layer on the polarizing plate 730.

A backplate 740 is disposed below the flexible substrate 710. When the flexible substrate 710 is formed of a plastic material such as polyimide, a manufacturing process of the flexible electroluminescent display device 700 is conducted in a state where a support substrate formed of glass is disposed below the flexible substrate 710, and after the manufacturing process is completed, the support substrate may be separated and released.

Since components for supporting the flexible substrate 710 are necessary even after the support substrate is released, the backplate 740 for supporting the flexible substrate 710 may be disposed below the flexible substrate 710. The backplate 740 may be disposed adjacent to the bending area B/A in other areas of the flexible substrate 710 except for the bending area B/A.

The backplate 740 may be formed of a plastic thin film formed of polyimide, polyethylene naphthalate (PEN), polyethylene terephthalate (PET), polymers, or a combination of these polymers.

A support member 770 is disposed between the two back plates 740, and the support member 770 may be bonded to the backplate 740 by an adhesive layer 760. The support member 770 may be formed of a plastic material such as polycarbonate (PC), polyimide (PI), polyethylene naphthalate (PEN), polyethylene terephthalate (PET), polymers, and combinations of these polymers, or the like. A strength of the support member 770 formed of these plastic materials may be controlled by adding additives to increase a thickness and strength of the support member 770. In addition, the support member 770 may be formed of glass, ceramic, metal, or other rigid materials, or a combination of the foregoing materials.

The micro-coating layer 750 is disposed on the bending area B/A of the flexible substrate 710. The micro-coating layer 750 may be formed to cover one side of the barrier film 720.

Since micro-cracks may be generated in the micro-coating layer 750 due to tensile force acting on a line unit disposed on the flexible substrate 710 during a bending operation, resin is coated to have a thin thickness at a bending location, thereby serving to protect the like.

The micro-coating layer 750 may adjust a neutral plane of the bending area B/A. The neutral plane refers to a virtual surface on which no stress occurs because compressive force and tensile force that are applied to a structure cancel each other out when the structure is bent. When two or more structures are stacked, a virtual neutral plane may be formed between the structures. When an entirety of the structures is bent in one direction, the structures disposed in a bending direction with respect to the neutral plane are compressed by bending and thus, are subjected to compressive force. On the contrary, structures disposed in a direction opposite to the bending direction based on the neutral plane are stretched by bending and thus, are subjected to tensile force. In this case, structures are generally more vulnerable when subjected to tensile force among the same levels of compressive force and tensile force, so a probability of cracks occurring when being subjected to tensile force is higher.

The flexible substrate 710 disposed below the neutral plane is compressed and thus, is subjected to compressive force, and lines disposed thereabove may be subjected to tensile force, and thus cracks may occur due to the tensile force. Therefore, to minimize tension on the line, it may be located on the neutral plane.

By disposing the micro-coating layer 750 on the bending area B/A, the neutral plane may be raised upwardly, and the neutral plane may be formed at the same location as the line or located at a location higher than the neutral plane. Thus, the micro-coating layer 750 may not be subjected to stress during bending or may be subjected to compressive force, so that the occurrence of cracks may be suppressed.

The micro-coating layer 750 may be formed of resin, an acrylic material, or urethane acrylate, but is not limited thereto.

An insulating layer 780 is connected to an end of the flexible substrate 710. Various lines are formed on the insulating layer 780 to transmit signals to the pixels disposed in the active area A/A. The insulating layer 780 is formed of a material that has flexibility so that it may be bent. A driving element may be mounted on the insulating layer 780, and together with the insulating layer 780, it forms a driving package such as a chip on film (COF). It is connected to lines formed on the insulating layer 780 and provides driving signals and data to the pixels disposed in the active area A/A.

A circuit board connected to the insulating layer 780 may receive image signals from the outside and apply various signals to the pixels disposed in the active area A/A, and may be a printed circuit board.

The exemplary aspects of the present disclosure may also be described as follows:

According to an aspect of the present disclosure, there is provided a display device. The display device comprises a flexible substrate including an active area including a plurality of pixels and a non-active area adjacent to the active area, the non-active area including a bending area bent in a first direction; a pattern unit disposed on the flexible substrate in the bending area and including concave portions and convex portions; and a plurality of lines disposed on the pattern unit.

The pattern unit may include a plurality of sub-patterns spaced apart from each other and repeatedly disposed in the first direction.

The plurality of sub-patterns may have a shape in which they extend and elongate in a second direction perpendicular to the first direction.

The sub-patterns may include a plurality of first sub-patterns repeatedly disposed in the first direction; and a plurality of second sub-patterns disposed adjacent in a second direction perpendicular to the first direction based on the first sub-patterns and repeatedly disposed in the first direction.

At least one corner of the first sub-patterns may be connected to at least one corner of the second sub-patterns.

The plurality of sub-patterns may be shifted in the first direction by a predetermined distance and disposed continuously in a second direction perpendicular to the first direction.

Each of the plurality of sub-patterns may have a circular shape, a quadrangular shape, a hexagonal shape, an octagonal shape, a polygonal shape with rounded corners, or a polygonal shape with cut corners, in a plan view.

The concave portion and the convex portion may be repeatedly disposed in the first direction. The plurality of lines may extend in the first direction along upper surfaces of the concave portion and the convex portion.

Each of a lower surface of the concave portion and the upper surface of the convex portion may have a round shape.

An inclination of the pattern unit may continuously change from the concave portion to the convex portion in a cross-section.

At least one insulating layer may be disposed on the bending area. The pattern unit may include a plurality of groove portions repeatedly disposed in a direction in which the plurality of lines extend and formed in the at least one insulating layer.

At least a portion of the plurality of lines may be disposed to contact the flexible substrate in the groove or to contact another insulating layer disposed between the flexible substrate and the at least one insulating layer.

The flexible display device may further comprise a thin film transistor disposed on the flexible substrate corresponding to the active area; a first planarization layer disposed on the thin film transistor; a connection electrode disposed on the first planarization layer and connected to the thin film transistor; a second planarization layer disposed on the connection electrode; and a display unit including a light emitting element disposed on the second planarization layer and electrically connected to the connection electrode. The first planarization layer and the second planarization layer extend from the active area to the bending area.

The pattern unit may be formed of the first planarization layer, and the second planarization layer may be disposed on the plurality of lines.

The pattern unit may include the first planarization layer and the second planarization layer.

The flexible substrate may include a first polyimide layer, an inorganic insulating layer on the first polyimide layer, and a second polyimide layer on the inorganic insulating layer, and the pattern unit may be formed of the second polyimide layer.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A flexible display device, comprising:
a flexible substrate including an active area including a plurality of pixels and a non-active area adjacent to the active area, the non-active area including a bending area bendable in a first direction;
a pattern unit disposed on the flexible substrate in the bending area and including a plurality of concave portions and convex portions; and
a plurality of lines disposed on the pattern unit.

2. The flexible display device of claim 1, wherein the pattern unit includes a plurality of sub-patterns spaced apart from each other and repeatedly disposed in the first direction.

3. The flexible display device of claim 2, wherein the plurality of sub-patterns have a shape in which they extend and elongate in a second direction perpendicular to the first direction.

4. The flexible display device of claim 2, wherein the sub-patterns include:
a plurality of first sub-patterns repeatedly disposed in the first direction; and
a plurality of second sub-patterns disposed adjacent in a second direction perpendicular to the first direction based on the first sub-patterns and repeatedly disposed in the first direction.

5. The flexible display device of claim 4, wherein at least one corner of the first sub-patterns is connected to at least one corner of the second sub-patterns.

6. The flexible display device of claim 2, wherein the plurality of sub-patterns are shifted in the first direction by a predetermined distance and disposed continuously in a second direction perpendicular to the first direction.

7. The flexible display device of claim 2, wherein each of the plurality of sub-patterns has a circular shape, a quadrangular shape, a hexagonal shape, an octagonal shape, a polygonal shape with rounded corners, or a polygonal shape with cut corners, in a plan view.

8. The flexible display device of claim 1, wherein the concave portion and the convex portion are repeatedly disposed in the first direction, and
wherein the plurality of lines extend in the first direction along upper surfaces of the concave portion and the convex portion.

9. The flexible display device of claim 8, wherein each of a lower surface of the concave portion and the upper surface of the convex portion has a round shape.

10. The flexible display device of claim 9, wherein an inclination of the pattern unit continuously changes from the concave portion to the convex portion in a cross-section.

11. The flexible display device of claim 1, wherein at least one insulating layer is disposed on the bending area, and
wherein the pattern unit includes a plurality of groove portions repeatedly disposed in a direction in which the plurality of lines extend and formed in the at least one insulating layer.

12. The flexible display device of claim 11, wherein at least a portion of the plurality of lines is disposed to contact the flexible substrate in the groove or to contact another insulating layer disposed between the flexible substrate and the at least one insulating layer.

13. The flexible display device of claim 1, further comprising:
a thin film transistor disposed on the flexible substrate corresponding to the active area;
a first planarization layer disposed on the thin film transistor;
a connection electrode disposed on the first planarization layer and connected to the thin film transistor;
a second planarization layer disposed on the connection electrode; and
a display unit including a light emitting element disposed on the second planarization layer and electrically connected to the connection electrode,
wherein the first planarization layer and the second planarization layer extend from the active area to the bending area.

14. The flexible display device of claim 13, wherein the pattern unit is formed of the first planarization layer, and the second planarization layer is disposed on the plurality of lines.

15. The flexible display device of claim 13, wherein the pattern unit includes the first planarization layer and the second planarization layer.

16. The flexible display device of claim 1, wherein the flexible substrate includes a first polyimide layer, an inorganic insulating layer disposed on the first polyimide layer, and a second polyimide layer disposed on the inorganic insulating layer, and
wherein the second polyimide layer constitutes the pattern unit.

17. A flexible display device, comprising:
a substrate including an active area having a plurality of pixels and a non-active area having a bending area bendable along a bending direction;
a plurality of stress reducing parts disposed on the flexible substrate in the bending area and extending along the bending direction or a different direction from the bending direction;
a plurality of circuit lines disposed to match a contour of the plurality of stress reducing parts and extending along the different direction from the bending direction; and
a circuit line protecting layer covering the plurality of circuit lines.

18. The flexible display device of claim 17, wherein the plurality of stress reducing parts includes a plurality of first patterns repeatedly disposed along the bending direction, and a plurality of second patterns disposed adjacent in the different direction from the bending direction and repeatedly disposed along the bending direction.

19. The flexible display device of claim 18, wherein at least one corner of the first patterns is connected to at least one corner of the second patterns.

20. The flexible display device of claim 18, wherein the plurality of second patterns are disposed to be shifted from the plurality of first patterns along the bending direction and extends to the different direction from the bending direction.
